(19) United States
(12) Patent Application Publication
(10) Pub. No.: US 2010/0009550 A1
(43) Pub. Date: Jan. 14, 2010

(54) METHOD AND APPARATUS FOR MODIFYING INTEGRATED CIRCUIT BY LASER

(75) Inventors: Susumu Tsujikawa, Tokyo (JP); Masanao Kamata, Tokyo (JP); Tetsumi Sumiyoshi, Tokyo (JP)

Correspondence Address: PEARNE & GORDON LLP, 1801 EAST 9TH STREET, SUITE 1200, CLEVELAND, OH, 44114-3108, US

(73) Assignees: CYBER LASER, INC., Tokyo (JP); MEERE COMPANY, INC., Gyeonggi-do (KR)

(21) Appl. No.: 12/517,651

(22) PCT Filed: Dec. 7, 2007
(86) PCT No.: PCT/JP2007/073672

§ 371 Date: Aug. 24, 2009

(30) Foreign Application Priority Data
Dec. 8, 2006 (JP) 2006-332663

(51) Int. Cl. H01L 21/268; B23K 26/00

(52) U.S. Cl. 438/798; 219/121.78; 219/121.85; 257/E21.347

(57) ABSTRACT

[PROBLEMS] To provide a method and an apparatus for cutting a conductive link of a redundant circuit in a semiconductor circuit.

[MEANS FOR SOLVING PROBLEMS] A method is provided for selectively cutting a plurality of conductive links embedded in a protection layer which covers at least the conductive links in a semiconductor device formed on a semiconductor substrate. A focused beam is aligned with a target link, a first pulsed laser beam having a short laser wavelength of 400 nm or shorter and a second pulsed laser beam having a wavelength longer than 400 nm are generated, the first and the second pulsed laser beams are overlapped and applied onto the conductive link from over the protection layer. Preferably, the second pulsed laser is applied after the first pulsed layer in terms of time.

### TECHNICAL FIELD

The present invention relates to integrated circuits formed on semiconductor substrates, particularly to those in which the integrated circuits include logic circuits such as DRAM and SRAM, offering a method and apparatus for modification preventing damage in the peripheral structural portions of electrically conductive links included inside devices, forming conductive link structures at a high integration density, and enabling selective laser severance of conductive links as needed.

### BACKGROUND ART

In the electronics industry, the downsizing of DRAM and SRAM is progressing annually, in connection with which their internal circuitry is becoming more highly integrated. A matrix arrangement formed by repeating structurally similar circuits will include redundant circuits. These redundant circuits are used to salvage the functionality of semiconductor integrated circuits by allowing defective circuits and conductive links to be severed. The severance of conductive links is performed using focused laser beams; a laser focal spot greater than the width of the link is shone onto the link in order to sever it. In this case, the higher density of the internal structure of the integrated circuits makes the spacing between the conductive link and adjacent links smaller, so the laser spot size must be smaller than the link spacing.

Since the silicon in semiconductor substrates has poor absorption, infrared (IR) lasers with wavelengths of 1.2 μm to 3 μm that are highly absorbed by the materials of conductive links have conventionally been favored for use, thus enabling methods of vaporizing only the links without damaging the substrate. However, since the wavelengths of IR lasers govern the size of the focal spots, the size of conductive links must be made larger than that of other components, despite the current trends which demand further downsizing.

Thus, attempts have been made to use lasers of shorter wavelength, but these have encountered problems. When using ultraviolet (UV) lasers, the processing proceeds from the surface, so that if there is a protective layer over the link, the link layer must be removed after removing this protective layer, thus requiring irradiation with a plurality of pulses of a pulsed UV laser (Patent Document 5). Since UV lasers can be tightly focused, methods involving coating with a resist layer before a step of severing a link by etching, exposing only the areas directly above selected link layers focused UV spots, then removing the resist in a development step, and finally etching to sever the link (Patent Document 8) have been considered. Furthermore, the use of visible (VIS) lasers with a wavelength about half that of IR lasers has been considered, but they can damage peripheral structures.

A conventional first embodiment will be explained with reference to FIG. 1. A passivation layer 2 is deposited on a semiconductor substrate 1 of silicon or the like, a conductive link 3 with electrodes 4 on both sides is set thereon, and a protective passivation layer 5 is provided thereon. When irradiated with an pulsed IR laser 6, the portion of the passivation layer 5 and the conductive link 3 in the area irradiated with the laser beam is subjected to vaporization as shown in FIG. 2, thus severing the conductive link and forming a conductive link severed portion 7. FIG. 3 shows a plan view, giving the positional relationship between the beam position and link when removing a conductive link 3 by irradiating with an IR laser of spot size 10 without damaging the semiconductor substrate 1.

When an IR laser of wavelength 1.2 μm to 3 μm is used, the transmission rate with respect to silicon is high, so the damage to the silicon substrate is minute. However, the focused laser spot size 10 must be enlarged, thus requiring a distance of about 8 to 10 μm for the spacing 11 between conductive links. This presents an obstacle to the design of highly integrated circuits. On the other hand, if a pulsed VIS laser beam 65 is used to make the spot size less than half that of an IR laser, then after the conductive link has been severed, damage such as cracks can tend to occur around the severed portion. Additionally, peeling can occur between the conductive links and the passivation layer 2 on the semiconductor substrate of FIG. 2. These are problematic for the reliability of integrated circuits. The reason for this can be inferred to be due to the fact that the conductive link undergoes explosive vaporization where the protective passivation layer formed on the conductive link is transparent with respect to visible lasers, thus applying shocks to its periphery and causing damage such as cracks and peeling.

Patent Document 1: U.S. Pat. No. 5,265,114
Patent Document 2: U.S. Pat. No. 5,473,624

Patent Document 3: U.S. Pat. No. 5,569,398

Patent Document 4: U.S. Pat. No. 6,025,256

Patent Document 5: U.S. Pat. No. 6,065,180

Patent Document 6: U.S. Pat. No. 6,297,541

Patent Document 7: U.S. Pat. No. 6,574,250

Patent Document 8: U.S. Pat. No. 6,593,542

Patent Document 9: U.S. Pat. No. 6,979,798

Patent Document 10: Japanese Patent Application, Publication No. 2000-514249T

### DISCLOSURE OF THE INVENTION

### Problems to be Solved by the Invention

The problem addressed by the present invention is that of offering a method and apparatus for severing conductive links by laser, which prevents damage in the periphery of the areas severed by the links, when severing conductive links using the outputs of repetitive Q-switched laser pulses.

### Means for Solving the Problems

In order to address the aforementioned problem, the present invention offers a method of modifying an integrated circuit by a laser that severs, by selective laser irradiation, a plurality of conductive links buried by a protective layer covering at least the conductive links inside a semiconductor integrated circuit formed on a semiconductor substrate, the method of modifying an integrated circuit by a laser comprising a step of positioning a laser onto a target conductive link; a step of generating a first pulsed laser which is an ultraviolet beam with a laser wavelength of 400 nm or less and a second pulsed laser which is a visible beam with a wavelength of greater than 400 nm; a step of superimposing the first and second pulsed lasers; and a step of severing said conductive links by irradiating with the superimposed first and second pulsed lasers from above said protective layer.

Additionally, in order to address the aforementioned problem, the present invention offers an apparatus for modifying an integrated circuit by a laser that severs, by selective laser irradiation, a plurality of conductive links buried by a protective layer covering at least the conductive links inside a semiconductor integrated circuit formed on a semiconductor substrate, the apparatus for modifying an integrated circuit by a laser comprising means for positioning the laser onto a target conductive link; means for generating a first pulsed laser which is an ultraviolet beam with a laser wavelength of 400 nm or less and a second pulsed laser which is a visible beam with a wavelength of greater than 400 nm; and means for superimposing the first and second pulsed lasers.

### EFFECTS OF THE INVENTION

By irradiating conductive links with a multi-wavelength pulsed laser by focusing superimposed laser pulses of a UV laser and a VIS laser using a Q-switched laser cavity in the IR wavelength range and harmonic generating technology achieved by using non-linear optical crystals on the output pulses thereof in the severance of a multilayer film consisting of a passivation layer and a conductive link according to the present invention, the conductive link can be severed by vaporizing parts of a multilayer structure in the laser beam irradiation region having different optical and thermal physical properties. The invention prevents the occurrence of cracks and interlayer peeling in the peripheral portions of the conductive links which sometimes occur conventionally with irradiation using only pulsed lasers in the VIS wavelength range.

Furthermore, since the UV and VIS wavelength regions are used for the wavelengths of the laser beams, the wavelengths are shorter than those of IR lasers, as a result of which the focal spot size can be reduced to less than half that of the infrared lasers of wavelength 1.2 μm to 3.0 μm transmitted by silicon which have conventionally been used for processing, thereby enabling the width of the link arrangements of the integrated circuits and the spacing between adjacent links to be reduced from the conventional distances, so as to allow for higher integration. Furthermore, by superimposing lasers of UV light and VIS light, it is possible to form a finer focal spot, and to expand the range of selection of physical properties of materials forming the passivation layer and conductive links to be irradiated. This greatly contributes to production of highly reliable and highly integrated memories.

### BRIEF DESCRIPTION OF THE DRAWINGS

FIG. 1 A diagram explaining a processing method using conventional laser beam irradiation relating to the invention.

FIG. 2 A section view of the conventional conductive link in the apparatus structure of FIG. 1 after severance.

FIG. 3 A plan view of the conventional conductive link of FIG. 1 for explaining the problems thereof.

FIG. 4 A structural diagram for a first embodiment of the present invention.

FIG. 5 A section view for explaining the conductive link for a first embodiment of the method of the present invention.

FIG. 6 A section view for explaining the conductive link after carrying out a first embodiment of the method of the present invention.

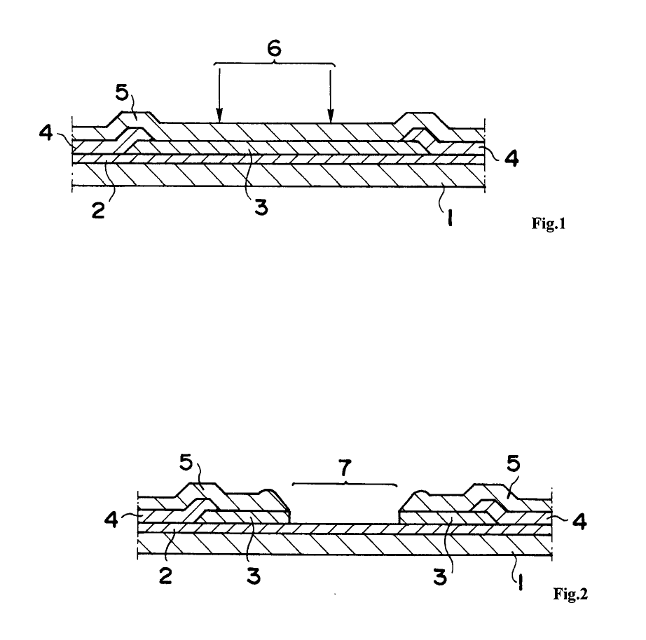

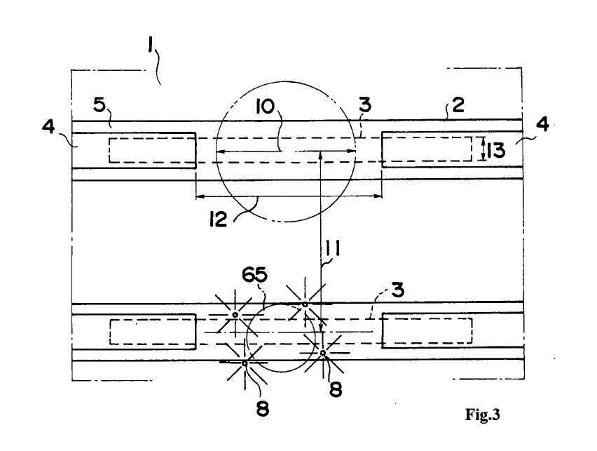

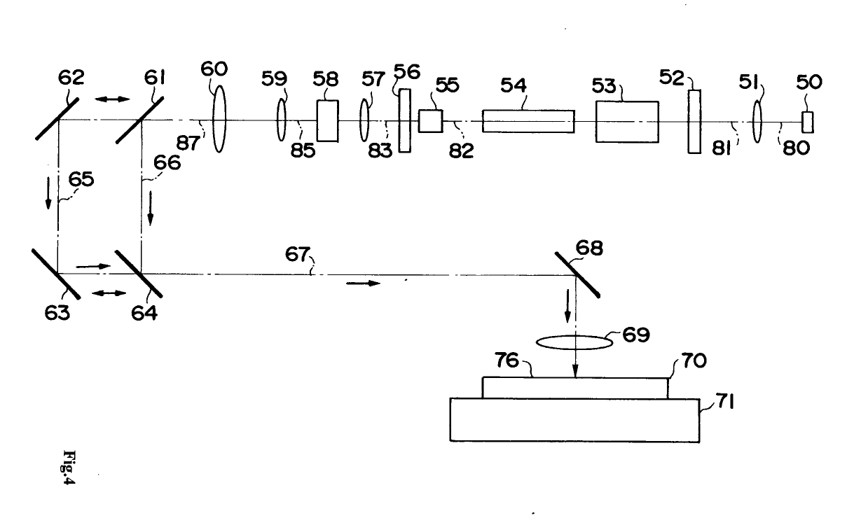

### BEST MODES FOR CARRYING OUT THE INVENTION

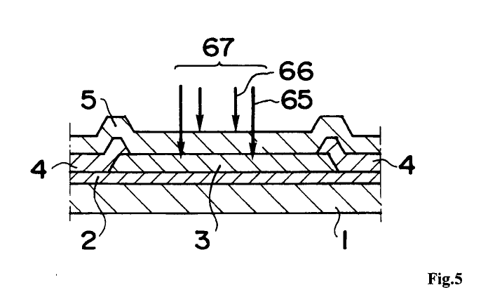

Herebelow, preferred embodiments of the present invention will be explained with reference to FIGS. 4-6.

### Embodiment 1

FIG. 4 shows a structure for generating a multi-wavelength pulsed laser. A semiconductor substrate 70 of silicon or the like, on which is formed a semiconductor integrated circuit, is mounted on a precision positioning table 71. A laser beam is set at a selected position on the conductive link 76 of the integrated circuit, and a condenser lens 69 is installed at a position corresponding to the link in order to focus light on the conductive link 76. A multi-wavelength laser beam 67 on which a pulsed UV laser beam 66 and a pulsed VIS laser beam 65 have been superimposed is reflected by a fully reflective mirror 68 and focused by the condenser lens 69. The focal point is shined at the center of the conductive link. The generation of the processing multi-wavelength laser beam 67 occurs as follows.

A laser medium 54 such as an Nd:YAG laser rod, an ultrasonic Q switch 53 and a non-linear optical crystal 55 are placed between the laser cavity mirrors 56 and 52. An optical excitation beam 80 which is a dispersive oscillator beam from a semiconductor laser diode 50 matching the excitation wavelength is focused to a convergent beam 81 by the condenser lens 51, and focused onto the laser medium 54 which is a laser rod via the mirror 52. The mirror 52 has highly reflective properties with respect to the laser oscillator wavelength, while having a high transparency to the wavelength of the optical excitation beam 80. The rod axis and the optical excitation beam 80 are arranged coaxially so as to optically excite the laser rod with the convergent beam 81. As a result, active ions distributed inside the laser medium are excited, having an optical amplification function due to an inversion distribution.

Q-switched laser pulses are generated by controlling the ultrasonic Q switch 53 to turn on/off the optical loss of the oscillator optical path 82 between the laser cavity mirrors 52-56. In the Q switch 53, the optical loss can be controlled by the presence or absence of diffraction on the transmitted light, by turning on/off the RF power applied to a transducer (not shown) that generates acoustic waves to form coarse-dense waves of refractive index inside an ultrasonic prism (not shown) medium receiving the acoustic waves.

When Q-switched laser pulses are generated in the oscillator path 82 in the cavity, a beam which is a mixture of the fundamental wavelength λ of the laser radiation from the active ions and the wavelength λ/2 of the second order harmonic from the non-linear optical crystal 55 placed in the cavity optical path is released from the cavity through the laser cavity mirror 56 as the beam 83. This laser cavity mirror 56 has a high transparency for the second order harmonic, and a high reflectance for the fundamental wavelength of the laser oscillator. As a result, the power of the laser oscillator fundamental wave component collects inside the cavity to achieve a high power density, and is efficiently converted to a higher order harmonic by the nonlinear crystal. The converted higher order harmonic component is not reflected by the laser cavity mirror 56, and is therefore emitted from the cavity as the beam 83.

In the case of Nd:YAG, the oscillation wavelength λ of the fundamental wave is 1064 nm, the wavelength λ/2 of the VIS beam which is the second order harmonic is 532 nm, the wavelength λ/3 of the third order harmonic is 355 nm and the wavelength λ/4 of the fourth order harmonic is 266 nm. In this invention, VIS is defined as wavelengths exceeding 400 nm and up to 700 nm, and UV as wavelengths of 400 nm or less. Therefore, the second order harmonic is a VIS beam and the third and fourth order harmonics are UV beams.

When using a medium other than an Nd:YAG laser rod as the laser medium 54, where the wavelength of the fundamental wave of the laser oscillator is in the VIS range, and the second and third order harmonics are in the UV range, then the wavelength of the fundamental wave can be used as the pulsed VIS laser and either of the harmonics can be used as the pulsed UV laser.

The beam 83 emitted from the cavity is further guided to a nonlinear crystal 58 to convert it to a third order harmonic (wavelength λ/3) which is a mixture of the second order harmonic and the fundamental wave having a shorter wavelength, or to a fourth order harmonic (wavelength λ/4) of the fundamental wave as a harmonic of the second order harmonic. In order to improve the conversion efficiency to higher harmonics by means of nonlinear optical crystals, a condenser lens 57 is used to focus the light in order to increase the power density of the input beam to the nonlinear crystal, and a nonlinear optical crystal 58 is placed near the focal point so as to convert the beam to a superimposed beam 85 including UV beams of wavelength λ/3 or λ/4.

In order to collimate the superimposed beam 85 consisting of the VIS beam and the UV beam to make it parallel again, lenses 59, 60 are provided to convert the beam to a parallel beam 87. The parallel beam 87 is split to a pulsed VIS laser beam 65 and a pulsed UV laser beam 66 by a beam splitter 61. The pulsed UV laser beam 66 is directed to the beam mixer 64 via a short optical path, and the pulsed VIS laser beam 65 is delayed via a detour optical path consisting of fully reflective mirrors 62, 63. At the beam mixer 64, the pulsed UV laser beam 66 and the pulsed VIS laser beam 65 are once again superimposed on the same axis, to obtain a multi-wavelength laser beam 67 for severing the conductive link 76. The beam splitter 61 and beam mixer 64 can be omitted if there is no need to impart a delay to the pulsed VIS laser beam 65. The multi-wavelength laser beam 67 is directed via the fully reflective mirror 68 and the condenser lens 69 to the conductive link 76, where the passivation layer and the conductive link are vaporized.

When imparting a delay to the pulsed VIS laser beam 65, a pulsed UV laser beam 66 is shone with the focal point of the condenser lens 69 at the protective passivation layer 5 shown in the section view of the conductive link in FIG. 5, and the pulsed VIS laser beam 65 is shone after aligning the focal point of the condenser lens 69 to the conductive link within the delay time.

As shown in FIG. 5, these two wavelength components, the pulsed VIS laser beam 65 and the pulsed UV laser beam 66, are shone as a processing multi-wavelength laser beam 67 onto the passivation layer 5 on a surface including the multilayered conductive link 3 formed on the semiconductor substrate 1 of silicon or the like. The passivation layer usually has high transparency with respect to visible light, but is absorbent and opaque to UV beams, so the passivation layer mainly absorbs the UV beam, so that the irradiated area is heated and softened, while on the other hand, the VIS beam which is shone onto the same area as the UV beam simultaneously or with a time delay has a small light absorption ratio at the surface, and reaches the internally located conductive link 3, which is heated and vaporized. The area of the conductive link 3 onto which the VIS beam is shone quickly reaches high temperatures and the pressure mounts explosively. When the passivation layer 5 provided on the surface layer is melted and softened by the UV beam, and the explosive pressure increase in the conductive link 3 due to the VIS beam affects the surrounding pressure, the softened UV-irradiated passivation layer on top is blown away to release the pressure. As a result, excessive stress impacts to the periphery due to the high temperatures of the inside conductive link 3 are reduced, thus avoiding the generation of cracks in the passivation layer 2 and the semiconductor substrate 1 below the conductive link 3, as well as damage to the areas peripheral to the link severance, such as due to peeling between the structural layers.

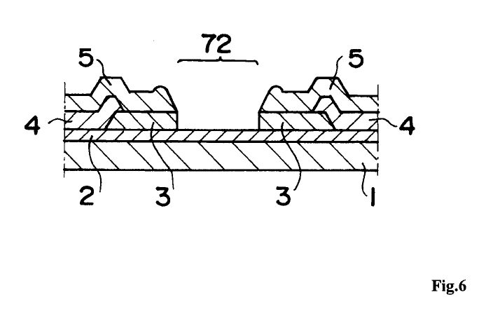

Thus, the creation of holes due to absorption of the explosive impacts at top layers is prevented by the softened layer formed by irradiation with the UV beam, while the severance is simultaneously achieved by vaporization of the internal conductive link 3, thus forming the processed portion cross section 72 shown in FIG. 6.

When shining the VIS laser pulse with a delay with respect to the UV laser pulse, the protective layer is heated and softened or vaporized by the previously shone UV laser pulse. Then, the conductive link is heated and vaporized by the VIS laser pulse. Since the protective layer is already softened or vaporized upon vaporization of the conductive link, excessive stress impacts are further reduced. As a result, the occurrence of cracks in peripheral portions and interlayer peeling is further prevented.

Additionally, these effects can be further improved by shining the UV laser pulses with the focal point at the protective layer, and shining the VIS laser pulses with the focal point at the conductive link.

Embodiments of the present invention have been described above. Modifications are clearly possible without departing from the technical concepts of the inventions recited in the claims.

### INDUSTRIAL APPLICABILITY

As an example of a possible application of the present invention, it is effective for severing the circuit elements of conductive links in redundant circuits on silicon wafers for semiconductor memory, as well as for removal inside the layers of a multi-layer electronic device. It can be applied to the trimming of capacitors, resistors and inductors having a passivation layer formed on the surface as a surface protection layer, the modification of LCD display panels, the modification of PDP display devices, the functional trimming of circuit boards, and other types of precision laser processing of semiconductor substrates. In the manufacture of highly integrated circuits, the downsizing of the processing width and the reduction in processing waste result in increased product yield, thereby reducing the production costs of electronic parts.

1. A method of modifying an integrated circuit by a laser that severs, by selective laser irradiation, a plurality of conductive links buried by a protective layer covering at least the conductive links inside a semiconductor I integrated circuit formed on a semiconductor substrate, the method of modifying an integrated circuit by a laser comprising:
a step of positioning a laser onto a target conductive link;
a step of generating a first pulsed laser which is an ultraviolet beam with a laser wavelength of 400 nm or less and a second pulsed laser which is a visible beam with a wavelength of greater than 400 nm;
a step of superimposing the first and second pulsed lasers; and
a step of severing said conductive links by irradiating with the superimposed first and second pulsed lasers from above said protective layer.

2. A method of modifying an integrated circuit by a laser in accordance with claim 1, wherein said step of severing involves irradiating said conductive links after temporally delaying the second pulsed laser with respect to the first pulsed laser.

3. A method of modifying an integrated circuit by a laser in accordance with claim 2, wherein the first pulsed laser is focused on said protective layer, and the second pulsed laser is focused on said conductive links.

4. A method of modifying an integrated circuit by a laser in accordance with claim 1, wherein the step of generating first and second pulsed lasers comprises a step of generating a fundamental wave from a single laser medium, a step of generating higher order harmonics of said fundamental wave, and a step of selecting said fundamental wave as the wavelength of the second pulsed laser and said higher order harmonic as the wavelength of the first pulsed laser, or a step of selecting said higher order harmonic as the wavelength of the second pulsed laser, and an even higher order harmonic as the wavelength of the first pulsed laser.

5. An apparatus for modifying an integrated circuit by a laser that severs, by selective laser irradiation, a plurality of conductive links buried by a protective layer covering at least the conductive links inside a semiconductor integrated circuit formed on a semiconductor substrate, the apparatus for modifying an integrated circuit by a laser comprising:
means for positioning the laser onto a target conductive link;
means for generating a first pulsed laser which is an ultraviolet beam with a laser wavelength of 400 nm or less and a second pulsed laser which is a visible beam with a wavelength of greater than 400 nm; and
means for superimposing the first and second pulsed lasers.

6. An apparatus for modifying an integrated circuit by a laser in accordance with claim 5, further comprising means for delaying the time at which the second pulsed laser irradiates said conductive links with respect to the first pulsed laser.

7. An apparatus for modifying an integrated circuit by a laser in accordance with claim 6, wherein the means for delaying is a means of making the optical path length of the second pulsed laser longer than that of the first pulsed laser.

8. An apparatus for modifying an integrated circuit by a laser in accordance with claim 6, further comprising means of focusing the second pulsed laser on said conductive links after focusing the first pulsed laser on said protective layer.

9. An apparatus for modifying an integrated circuit by a laser in accordance with claim 5, wherein the means for generating the first and second pulsed lasers comprises a single laser medium for generating a fundamental wave, means for generating higher order harmonics from said fundamental wave, and means for selecting said fundamental wave as the wavelength of the second pulsed laser and said higher order harmonic as the wavelength of the first pulsed laser, or means for selecting said higher order harmonic as the wavelength of the second pulsed laser, and an even higher order harmonic as the wavelength of the first pulsed laser.

10. A method of modifying an integrated circuit by a laser in accordance with claim 2, wherein the step of generating first and second pulsed lasers comprises a step of generating a fundamental wave from a single laser medium, a step of generating higher order harmonics of said fundamental wave and a step of selecting said fundamental wave as the wavelength of the second pulsed laser and said higher order harmonic as the wavelength of the first pulsed laser, or a step of selecting said higher order harmonic as the wavelength of the second pulsed laser, and an even higher order harmonic as the wavelength of the first pulsed laser.

11. A method of modifying an integrated circuit by a laser in accordance with claim 3, wherein the step of generating first and second pulsed lasers comprises a step of generating a fundamental wave from a single laser medium, a step of generating higher order harmonics of said fundamental wave, and a step of selecting said fundamental wave as the wavelength of the second pulsed laser and said higher order harmonic as the wavelength of the first pulsed laser, or a step of selecting said higher order harmonic as the wavelength of the second pulsed laser, and an even higher order harmonic as the wavelength of the first pulsed laser.

12. An apparatus for modifying an integrated circuit by a laser in accordance with claim 7, further comprising means of focusing the second pulsed laser on said conductive links after focusing the first pulsed laser on said protective layer.

13. An apparatus for modifying an integrated circuit by a laser in accordance with claim 6, wherein the means for generating the first and second pulsed lasers comprises a single laser medium for generating a fundamental wave, means for generating higher order harmonics from said fundamental wave, and means for selecting said fundamental wave as the wavelength of the second pulsed laser and said higher order harmonic as the wavelength of the first pulsed laser, or means for selecting said higher order harmonic as the wavelength of the second pulsed laser, and an even higher order harmonic as the wavelength of the first pulsed laser.

14. An apparatus for modifying an integrated circuit by a laser in accordance with claim 7, wherein the means for generating the first and second pulsed lasers comprises a single laser medium for generating a fundamental wave, means for generating higher order harmonics from said fundamental wave, and means for selecting said fundamental wave as the wavelength of the second pulsed laser and said higher order harmonic as the wavelength of the first pulsed laser, or means for selecting said higher order harmonic as the wavelength of the second pulsed laser, and an even higher order harmonic as the wavelength of the first pulsed laser.

15. An apparatus for modifying an integrated circuit by a laser in accordance with claim 8, wherein the means for generating the first and second pulsed lasers comprises a single laser medium for generating a fundamental wave, means for generating higher order harmonics from said fundamental wave, and means for selecting said fundamental wave as the wavelength of the second pulsed laser and said higher order harmonic as the wavelength of the first pulsed laser, or means for selecting said higher order harmonic as the wavelength of the second pulsed laser, and an even higher order harmonic as the wavelength of the first pulsed laser.
